(19) United States
(12) Patent Application Publication
(10) Pub. No.: US 2004/0070460 A1
(43) Pub. Date: Apr. 15, 2004

(54) Microwave oscillator

(76) Inventor: Phillip Norton, Lincoln (GB)

Correspondence Address: VENABLE, BAETJER, HOWARD AND CIVILETTI, LLP, P.O. BOX 34385, WASHINGTON, DC, 20043-9998, US

(21) Appl. No.: 10/471,797

(22) PCT Filed: Mar. 18, 2002
(86) PCT No.: PCT/GB02/01269

(30) Foreign Application Priority Data
Mar. 16, 2001 (GB) 0106581.2

(51) Int. Cl. H03B 7/14

(52) U.S. Cl. 331/107 DP

(57) ABSTRACT

A microwave oscillator comprises a semiconductor oscillating element, e.g. a Gunn diode (3) mounted at least partially within a dielectric substrate (1). The oscillating element is arranged, in use, to generate power at a predetermined fundamental frequency and at an harmonic frequency. The oscillator further comprises a circuit pattern (4) on the substrate arranged to transmit the power generated at the harmonic frequency to an output (10) whilst holding transmission of the power at the fundamental frequency.

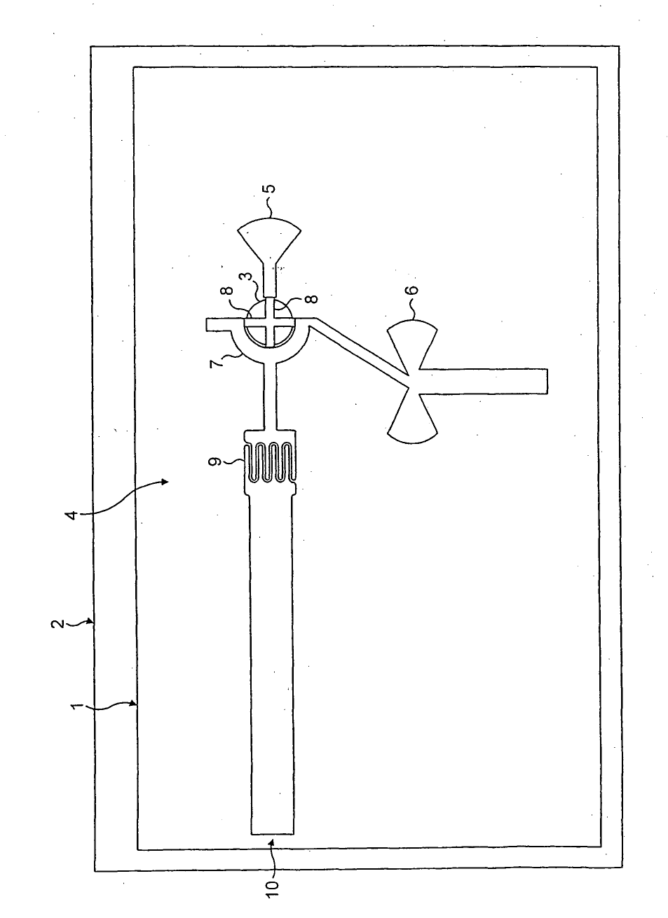

This invention relates to microwave oscillators such as may be found in, for example, vehicle safety systems involving radar.

Vehicle safety systems can generally be categorised as either crash protection systems or accident avoidance systems. Crash protection safety systems can minimise the effects of an accident, but an effective accident avoidance system can allow a driver to avoid an accident altogether. Vehicle radar is particularly suitable for use in accident avoidance systems. Another related application of vehicle radar is that of active cruise control (ACC), in which the speed of the vehicle is automatically set according to the distance and relative velocity of a vehicle or obstacle in the radar's field of “view”.

Vehicle radar systems employ a transmitter/receiver discretely mounted on the front of a vehicle. The maximum range that may be detected up to a target, such as an upcoming motor vehicle, is of a relatively short distance of about, say, several hundred metres. Therefore, such a radar system preferably uses radio waves in the microwave range, having a frequency of around 77 GHz.

Microwave oscillators for vehicle radar systems have typically employed an oscillating element, such as a Gunn diode, coupled to a waveguide cavity.

A problem which may be encountered with conventional microwave oscillators is that they are somewhat bulky, involve a high degree of mechanical design and assembly and often require mechanical tuning set-up techniques. The labour associated with the design, assembly and set-up of such oscillators greatly adds to the cost.

The invention provides a microwave oscillator comprising a semiconductor oscillating element mounted at least partially within a dielectric substrate, the oscillating element being arranged, in use, to generate power at a predetermined fundamental frequency and at an harmonic frequency, the oscillator further comprising a circuit pattern on the substrate arranged to transmit the power generated at the harmonic frequency to an output whilst inhibiting transmission of the power at the fundamental frequency.

Alternatively, the oscillating element may be arranged in use to generate power at a fundamental frequency and a plurality of harmonic frequencies, in which case the circuit pattern is arranged to allow transmission of power at one or more of the harmonics whilst blocking power generated at the other frequencies.

The provision of a circuit pattern on a substrate permits power at a desired frequency to be transmitted without the need for a waveguide cavity. The invention is smaller, less costly and more able to withstand mechanical vibration than the conventional cavity oscillator. Power generated at undesired frequencies, such as the fundamental, is held within the device by the circuit pattern; hence the frequency of the oscillator is less susceptible to external influences.

Preferably, the semiconductor oscillating element is a Gunn diode. Advantageously, the Gunn diode is a graded gap device employing hot electron injection. Such a device exhibits good performance over the operating temperature.

The invention will now be described, by way of example, with reference to, or as illustrated in, the accompanying drawing, which is a plan view of an oscillator constructed according to the invention.

With reference to the drawing, a dielectric substrate 1 is illustrated, mounted on a base 2, which is both electrically and thermally conductive. The base can serve as a ground plane, as well as providing a heat sink. The substrate 1 includes an opening, into which is inserted a Gunn diode 3. In this embodiment, the diode 3 is bonded to the metal base to provide good thermal contact. The Gunn diode may be a wafer-scale packaged device, the manufacture of which is described in our co-pending patent application No. GB 0015775.0.

The diode 3 is unpackaged, which feature provides greater compactness of the oscillator circuit. The substrate also has a circuit, indicated generally by the reference numeral 4, which may be applied using microstrip technology. The Gunn diode 3 is mounted in the opening in the substrate such that its upper surface lies in the same plane as the circuit 4. The circuit 4 includes a resonator 5, preferably of very high Q, associated with the Gunn diode 3. The circuit 4 also includes a bias filter 6. The necessary dc bias signal for the Gunn diode 3 is supplied to the cathode of the Gunn diode via the bias filter 6 and associated interconnect structure, by means of a bonding area 7, which partly surrounds the Gunn diode 3. Bond wires 8 connect the Gunn diode 3 to the oscillator circuit 4.

Output power is extracted from the Gunn diode 3 via an interdigital capacitor 9 to an output 10. The interdigital capacitor 9 also removes dc bias, which may otherwise be applied to the Gunn diode 3 from the output 10.

A Gunn diode 3 is one of a type of semiconductor elements that exhibits a negative resistance under certain conditions; when this is appropriately matched with a load impedance, oscillation results at a predetermined fundamental frequency. However, the diode will also generate power at harmonics of this frequency, which property is useful as conventional Gunn diodes can only oscillate up to approximately 60 GHz. In order 10 to achieve power at the desired 77 GHz frequency, the Gunn diode is arranged to oscillate with a fundamental frequency of approximately 38.5 GHz. Power generated at the second harmonic falls within the required frequency.

The dimensions of the circuitry are arranged so that power generated at the fundamental 15 frequency is substantially prevented from transmission by the circuit. For example, the circuit may prevent fundamental power transmission by a filtering process within the structure of the circuit tracks. In this manner fundamental power is held within the circuit pattern. The microstrip circuit only allows power at the second harmonic frequency to be passed to the output 10 via the interdigital capacitor 9.

The Gunn diode 3 may be arranged to oscillate at other harmonic frequencies, in which case the microstrip circuit 4 is configured so that a predetermined harmonic frequency is transmitted whilst the fundamental and/or any other harmonics are retained within the circuit pattern. This feature may render the circuit of the invention suitable for other applications.

Suitable materials for the dielectric substrate 1 include alumina, softboard materials, aluminium nitride (AIN) and quartz. The circuitry 4 may be realised by thin film or thick film conductors, or microwave PCB conductors.

Further variations may be made without departing from the scope of the invention. For example, the diode chip 3 is preferably a graded-gap device employing hot electron injection. However, a Gunn diode having multiple transit regions may be employed, with optional hot electron injection.

Furthermore, the Gunn diode 3 may take the form of a packaged device (the package being optionally hermetic), a mesa chip or a flip chip device. However, an unpackaged device is preferred, because it alleviates the problem of so-called package parasitics. The electrical performance of an IC package, such as signal quality and noise sensitivity, is directly affected by the package parasitics, which represent the contributions of the components of the package, for example, bond wires, internal package routing and external leads. The Gunn diode 3 may be planar, with connections for both the anode and the cathode on the same face of the chip. The diode may also be arranged with an integral heat sink.

In the aforedescribed configuration, the upper surface of the diode was in the same plane as the microstrip circuit pattern; however, this is not a necessary feature. The diode 3 may be located above or below the plane of the circuit pattern 4.

The output 10 of the oscillator may take the form of microstrip, waveguide or non-radiative dielectric (NRD) material.

In order to provide an accurate oscillator frequency, active laser tuning may be employed in order to modify elements of the circuit, typically the resonator 5. Laser tuning involves the use of a laser to remove small quantities of conductor material from a component or circuit in order to modify its properties, for example the power output or frequency. Laser tuning is usually effected in a plurality of locations, either in a predetermined sequence or on an ad hoc basis. This form of active tuning may be employed even if components of the oscillator circuitry are packaged. In this instance, the laser beam is admitted through small holes in the lid of the package, which holes are cut off above the frequency of the oscillator.

Optional frequency tuning of the device can be achieved by changing the bias voltage applied to the Gunn diode 3. Alternatively a varactor (not shown) may be incorporated in the fundamental circuitry, in order to provide a voltage-variable capacitance.

In use, the Gunn diode may be operated with the application of a constant DC bias. Alternatively, the input DC power may be pulsed at a frequency below the frequency of the oscillator ramp. This has the effect of reducing the average power being delivered, and therefore the power dissipated in the diode.

The oscillator of the invention may include control circuitry (not shown) arranged to provide an improved frequency ramp, i.e. the change in frequency with time (df/dt) when a linear voltage ramp is applied (dV/dt). The linearity provided by the control circuit may be related to characteristics of the Gunn diode, varactor (if used) or both.

The integrated circuit configuration of the invention renders the device easy to integrate with other components. The substrate may take the form of a more extensive layer, which includes other components of the radar system.

As well as being a microwave frequency source, the present invention may be adapted to act as a receiver. This is especially useful in vehicle radar systems, wherein a signal reflected from an obstacle needs to be received and processed by the vehicle radar. Therefore, the invention may also include circuitry arranged to detect and perform down-conversion of a reflected signal. The reflected signal may be received via a separate antenna feed arrangement, different from the antenna feed employed to transmit the signal. Alternatively, a single antenna may be used. This latter embodiment requires a circulator or switch in order to bias the circuitry alternately into “transmit” and “receive” states. The down-conversion mixer circuit may use Schottky diodes in beam-lead, flip-chip or naked die formats. Alternatively, a MMIC may be employed; or any device with an asymmetric INV characteristic, for example a planar doped barrier (PDB) diode; or a hetero-junction structure such as an asymmetric spacer and transit time (ASPATT) diode.

1. A microwave oscillator comprising a semiconductor oscillating element mounted at least partially within a dielectric substrate, the oscillating element being arranged, in use, to generate power at a predetermined fundamental frequency and at an harmonic frequency, the oscillator further comprising a circuit pattern on the substrate arranged to transmit the power generated at the harmonic frequency to an output whilst inhibiting transmission of the power at the fundamental frequency.

2. A microwave oscillator comprising a semiconductor oscillating element mounted at least partially within a dielectric substrate, the oscillating element being arranged, in use, to generate power at a predetermined fundamental frequency and at a plurality of harmonic frequencies, the oscillator further comprising a circuit pattern on the substrate arranged to transmit the power generated at a desired one of the frequencies to an output whilst inhibiting transmission of power at the other frequencies.

3. An oscillator as claimed in claim 1 or 2, in which the semiconductor oscillating element comprises a Gunn diode.

4. An oscillator as claimed in claim 3, in which the Gunn diode is a graded gap device.

5. An oscillator as claimed in claim 3, in which the Gunn diode includes a plurality of transit regions.

6. An oscillator as claimed in any one of claims 3 to 5, in which the Gunn diode employs hot electron injection.

7. An oscillator as claimed in claim 3, in which the Gunn diode is a mesa chip.

8. An oscillator as claimed in claim 3, in which the Gunn diode is a flip chip.

9. An oscillator as claimed in claim 3, in which the Gunn diode includes a heat sink.

10. An oscillator as claimed in any one of claims 3 to 9, in which the Gunn diode is packaged

11. An oscillator as claimed in any preceding claim in which the circuit pattern includes microstrip.

12. An oscillator as claimed in claim 11, in which the microstrip comprises thick film conductors.

13. An oscillator as claimed in claim 11, in which the microstrip comprises thin film conductors.

14. An oscillator as claimed in claim 11, in which the microstrip comprises microwave PCB conductors.

15. An oscillator as claimed in any preceding claim, further comprising a heat sink.

16. An oscillator as claimed in claim 15, in which the heat sink also provides a ground plane for the oscillator.

17. An oscillator as claimed in any preceding claim, in which the output comprises microstrip.

18. An oscillator as claimed in any one of claims 1 to 16, in which the output comprises a waveguide.

19. An oscillator as claimed in any one of claims 1 to 16, in which the output includes dielectric material.

20. An oscillator as claimed in any preceding claim, further comprising means arranged to inhibit transmission of dc bias from the output to the oscillating element.

21. An oscillator as claimed in claim 20, in which the means arranged to inhibit transmission of dc bias comprises a capacitor.

22. An oscillator as claimed in claim 21, in which the capacitor is an interdigital capacitor.

23. A microwave oscillator, substantially as hereinbefore described with reference to, or as illustrated in, the accompanying drawings.

24. A radar system incorporating a microwave oscillator as claimed in any preceding claim.

25. A vehicle radar system incorporating a microwave oscillator as claimed in any one of claims 1 to 23.

26. A vehicle incorporating vehicle radar as claimed in claim 25.

27. A method of manufacture of a microwave oscillator, comprising the steps of mounting a semiconductor oscillating element at least partially within a dielectric substrate and forming a circuit pattern on the substrate, which circuit pattern is arranged, in use, to allow transmission of a predetermined harmonic frequency generated by the oscillating element.

28. A method as claimed in claim 27, further comprising the step of removing conductor material from the circuit by means of a laser.

29. A method as claimed in claim 28, wherein a component of the oscillator is packaged, the method further comprising the step of providing at least one aperture in the package, through which light from the laser may be admitted.
